(19) United States
(12) Patent Application Publication
(10) Pub. No.: US 2013/0082690 A1
(43) Pub. Date: Apr. 4, 2013

(54) MEASURING ARRANGEMENT FOR DETECTING ALTERNATING CURRENTS

(71) Applicant: Phoenix Contact GmbH & Co., KG, Blomberg (DE)

(72) Inventors: Frank Hakemeyer, Horn-Bad Meinberg (DE); Christian Jurgenhake, Rietberg (DE); Carsten Thorner, Melle (DE)

(21) Appl. No.: 13/623,929

(22) Filed: Sep. 21, 2012

Related U.S. Application Data
(63) Continuation of application No. PCT/EP2011/054450, filed on Mar. 24, 2011.

(30) Foreign Application Priority Data
Mar. 24, 2010 (DE) 10 2010 012 691.8
Mar. 25, 2010 (DE) 10 2010 012 834.1

(51) Int. Cl. G01R 1/22

(52) U.S. Cl. CPC G01R 1/22
USPC 324/127

(57) ABSTRACT

The invention relates to a measurement arrangement for connection to an energy and power meter and for connection to a Rogowski coil for detecting of alternating currents of a conductor being metered. The measurement arrangement has an integrator circuit to create a voltage signal proportional to the detected alternating current and a voltage/current converter to create an output current that is proportional to the voltage signal created by the integrator circuit. Furthermore, the invention relates to a measurement system that has an above-described measurement arrangement and a Rogowski coil for detecting of alternating currents of a conductor being metered.

### CROSS-REFERENCE TO RELATED APPLICATIONS

This application is a continuation of International Application No. PCT/EP2011/054450, filed Mar. 24, 2011, which claims the benefit of German Application No. 10 2010 012 691.8 filed Mar. 24, 2010 and German Application No. 10 2010 012 834.1 filed Mar. 25, 2010, the entire disclosures of which are hereby incorporated by reference.

### FIELD

The invention concerns a measurement arrangement for detecting of alternating currents in general and in particular a measurement arrangement for detecting of alternating currents for measuring with an energy and power meter.

### BACKGROUND

Current measurement systems find application, e.g., in industrial facilities. Here, alternating currents are often measured with so-called current transformers. These current transformers—see FIG. 1—are based on the transformer principle. According to this principle, an output signal is provided that is proportional to the measured current.

As used herein, “proportional” means true in phase and proportional in amplitude.

However, it is to be expected that measurement with energy and power devices will also occur increasingly in the household, since electricity rates with active and reactive power metering are being increasingly introduced.

The output signal obtained is usually a 0 A to 1 A or a 0 A to 5 A current signal. This signal range results from the fact that moving-iron instruments have often and are often used for the measurement itself, having a certain relatively high power requirement, which is also taken correspondingly from the conductor being measured by means of the alternating magnetic field.

Current transformers are available in many designs. Often they are built as bushing transformers, in which the current carrying conductor being measured is led through an encapsulated ring core. This configuration requires a consideration of the mounting already during the installation, since a later mounting would require the loosening of a conductor, shifting of the current transformer, and reattachment. Such an activity is only possible with the conductor switched off, so that it results in a shutdown of the device drawing the power. Therefore, such bushing transformers are felt to be a disadvantage for a mounting later on.

In order to deal with this drawback, so-called hinged transformers have been developed, in which the ring core is in two pieces, so that the ring of the transformer can be opened and closed again by a hinge, making possible even a later introduction in an existing installation.

Alternatively, shunt measurements are also performed, in which the voltage dropping across an introduced known but small resistance is measured.

Furthermore, measurement is also done with systems having a Rogowski coil. The principle of these systems shall be briefly explained below by means of FIG. 2.

A conductor 110 is introduced in a specially wound air coil 100. If an impressed current I flows through this conductor according to a time variation as shown at bottom left, a voltage impulse V_{IN} will be induced in the coil 100 as the current varies. The variation of the voltage impulse is shown at bottom center as a function of time. In order to create from this induced voltage V_{IN} a signal proportional to the current that can be evaluated, the induced voltage signal must be subjected to a time integration in an integrating circuit 120, which is shown simplified as an appropriately hooked-up operational amplifier. The corresponding output signal of the integrator V_{OUT} is then proportional once more to the impressed current in the conductor 110, as shown bottom right.

Systems with a Rogowski coil have many advantages, for the measurement principle allowed a high accuracy in a large measurement range. Furthermore, the Rogowski coil due to its half-open nature can also easily be brought subsequently into an existing installation without this requiring a disconnection and a deinstallation of a conductor and then reinstallation of the conductor.

The drawback is that a system with a Rogowski coil cannot work with traditional power and energy metering systems, since the available currents are too low to put out appropriate power or to provide the necessary output signals that are expected by the meter (0-1 A or 0-5 A).

While alternative systems with Rogowski coil provide a nearly standardized d.c. voltage signal (0-10 V or 4-20 mA), this signal is only the root mean square (r.m.s.) value, that is, any phase information is lost here from the forming of the effective value, and so no active and reactive power can be determined with this signal.

### SUMMARY

It is therefore the problem of the present disclosure to make the Rogowski principle also available to traditional energy and power metering systems that expect a sufficient current signal as the input quantity.

The problem is solved by a measurement arrangement for connection to an energy and power meter and for connection to a Rogowski coil for detecting of alternating currents of a conductor being metered. The measurement arrangement has an integrator circuit to create a voltage signal proportional to the detected alternating current and a voltage/current converter to create an output current that is proportional to the voltage signal created by the integrator circuit.

In another embodiment the voltage/current converter of the measurement arrangement provides currents to the energy and power meter of up to 5 A or up to 1 A.

In another embodiment, the output power of the voltage/current converter is up to 5 VA.

In another embodiment, the output contains a passive current impressing stage.

In another embodiment, the Rogowski coil and the integrator circuit form a subassembly.

In another embodiment, the Rogowski coil, the integrator circuit and the voltage/current converter form a subassembly.

Furthermore, the problem is also solved by a measurement system that has an above-described measurement arrangement and a Rogowski coil for detecting of alternating currents of a conductor being metered.

In another embodiment, the measurement system also has an energy and power meter.

### BRIEF DESCRIPTION OF THE DRAWINGS

With the help of the following drawings, the invention shall be explained more closely.

FIG. 1 shows a current transformer working by the transformer principle.

FIG. 2 shows a measurement arrangement based on a Rogowski coil, which provides a voltage signal.

FIG. 3 shows an embodiment of a measurement arrangement or a measurement system according to a first embodiment of the invention.

FIG. 4 shows another embodiment of a measurement arrangement or a measurement system according to a first embodiment of the invention.

FIG. 5 shows a schematic circuit variant of the embodiments, which contains a passive current impressing stage.

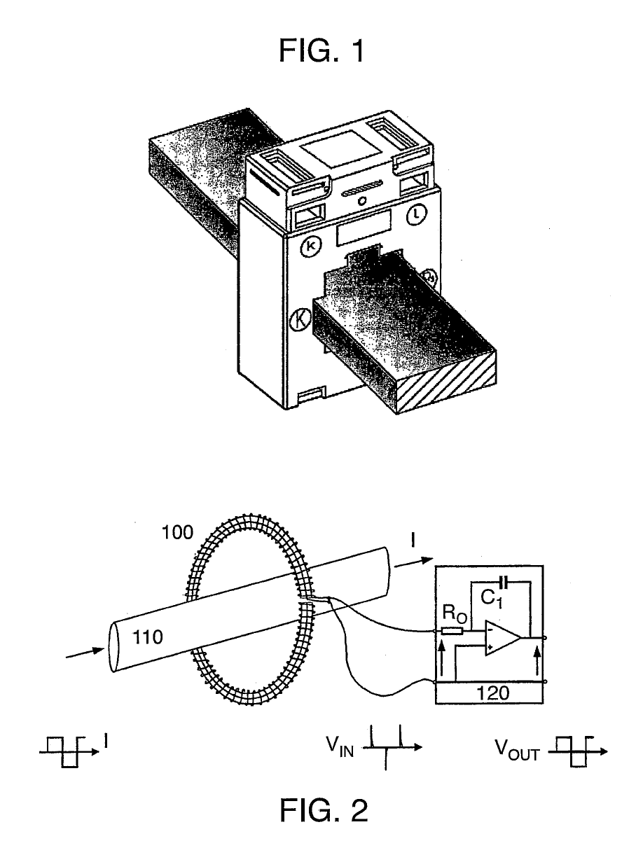

### DESCRIPTION OF PREFERRED EMBODIMENTS

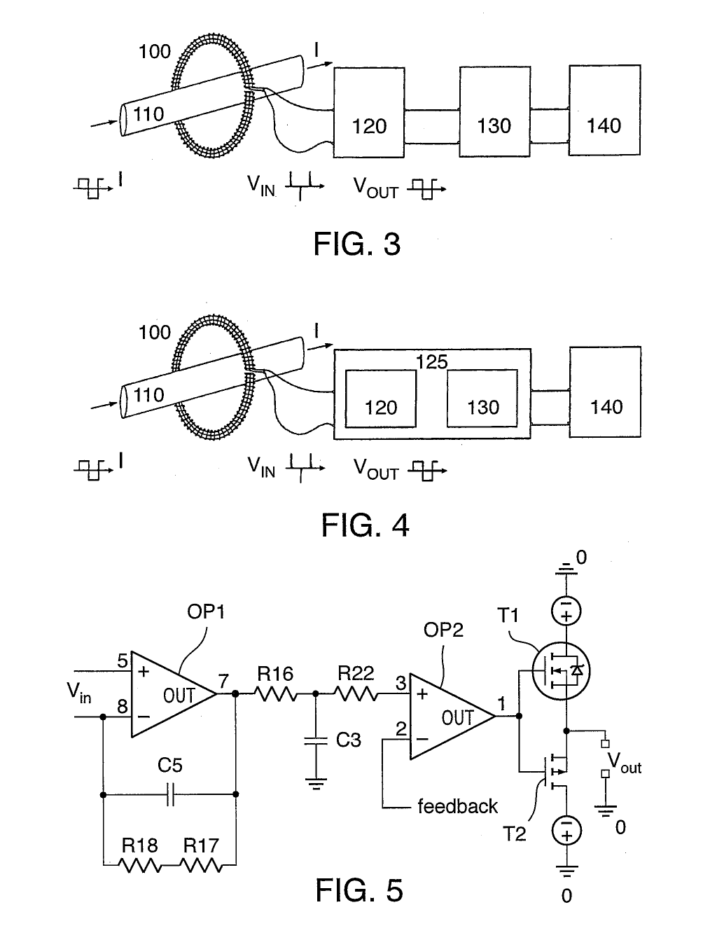

FIG. 3 shows schematically an embodiment of a measurement arrangement or a measurement system according to a first embodiment of the invention.

The measurement arrangement is suited to being connected to an energy and power meter 140. The energy and power meter 140 can be a traditional energy and power meter having a current input that is designed, e.g., for the range of 0-1 A or 0-5 A.

Furthermore, the measurement arrangement is also suited to being connected to a Rogowski coil 100 for detecting of alternating currents of a conductor 110 being metered.

The measurement arrangement itself has an integrator circuit 120 for creating a voltage signal proportional to the detected alternating current and a voltage/current converter 130 for creating an output current that is proportional to the voltage signal created by the integrator circuit.

In another embodiment, the Rogowski coil 100 and the integrator circuit 120 form a subassembly, i.e., that are placed in a common housing. Here, the voltage/current converter 130 can either be placed near the joint subassembly of the Rogowski coil 100 and the integrator circuit 120 or near the energy and power meter 140, the decision basically depending on which distances are to be bridged between the subassembly and the energy and power meter 140 and which resistance is expected due to the metering lines that connect the subassembly to the voltage/current converter 130 and the voltage/current converter 130 to the energy and power meter 140.

In another embodiment, the Rogowski coil 100, the integrator circuit 120 and the voltage/current converter 130 form a subassembly.

In another configuration of the embodiments, the voltage/current converter 130 of the measurement arrangement provides currents to the energy and power meter 140 of up to 5 A or up to 1 A.

In another configuration of the embodiments, the output power of the voltage/current converter 130 is up to 5 VA. This power is sufficient to carry out a low-power measurement and corresponds to the reduced input loads of the modern energy and power meter 140. Furthermore, this limitation also ensures that the design of the voltage/current converter 130 can be kept compact on the whole and thus an easy integration in existing installations is made possible.

In another configuration of the embodiments, the output contains a passive current impressing stage, which is represented as a schematic circuit variant in the right half of FIG. 5 and shall be explained below.

In FIG. 5, the signal obtained by a Rogowski coil 100 indicated by “In” at the left side of the drawing is supplied to an integrator circuit 120.

The integrator circuit has a first operational amplifier OP1, which is hooked up with a capacitor C5 and a resistor, here represented as a series resistor circuit of R18 and R17, in the feedback of the output signal.

The output signal of the integrator is now taken across a matching network consisting of R16, C3 and R22 to a voltage/current converter 130, which is now shown at the right side of the drawing. The matching network is not a necessary component and is shown only as an example.

The voltage/current converter 130 has a second operational amplifier OP2, which then converts the output signal of the first operational amplifier OP1 supplied by a matching network optionally present, i.e., that of the voltage signal, into a signal for driving a passive current impressing stage, for example, formed by two transistors T1 and T2 as shown at the right side of FIG. 5. Even though this circuit requires an outside current supply of the transistors T1 and T2, this variant can be of advantage, e.g., when the metering lines are of great length.

In one embodiment of the invention, an overall measurement system is provided, having an aforementioned measurement arrangement of integrator 120 and voltage/current converter 130, as well as a Rogowski coil 100 for detecting the alternating currents of a conductor being metered, in order to be connected to a traditional energy and power meter 140.

In another embodiment, the measurement system also has this energy and power meter 140.

1. A measurement arrangement for connection to an energy and power meter and for connection to a Rogowski coil for detecting alternating currents of a conductor being metered, comprising:
an integrator circuit to create a voltage signal proportional to the detected alternating current; and
a voltage/current converter to create an output current that is proportional to the voltage signal created by the integrator circuit.

2. The measurement arrangement according to claim 1, wherein the voltage/current converter provides currents of up to 5 A.

3. The measurement arrangement according to claim 1, wherein the voltage/current converter provides currents of up to 1 A.

4. The measurement arrangement according to claim 1, wherein the output power of the voltage/current converter is up to 5 VA.

5. The measurement arrangement according to claim 1, wherein the output contains a passive current impressing stage.

6. The measurement arrangement according to claim 1, wherein the Rogowski coil and the integrator circuit form a subassembly.

7. The measurement arrangement according to claim 1, wherein the Rogowski coil, the integrator circuit and the voltage/current converter form a subassembly.

8. A measurement system, comprising:
a measurement arrangement according to claim 1; and
a Rogowski coil for detecting alternating currents of a conductor being metered.

9. The measurement system according to claim 8, further comprising an energy and power meter.
